(19) United States
(12) Patent Application Publication
(10) Pub. No.: US 2020/0243695 A1
(43) Pub. Date: Jul. 30, 2020

(54) SOLAR CELL CONNECTOR HAVING A FUNCTIONAL LONGITUDINAL COATING

(71) Applicant: Heraeus Deutschland GmbH & Co. KG, Hanau (DE)

(72) Inventors: Andreas Henning, Sinntal-Mottgers (DE); Markus Koening, Dieburg (DE)

(21) Appl. No.: 16/635,119

(22) PCT Filed: Jul. 3, 2018
(86) PCT No.: PCT/EP2018/067907

§ 371 Date: Jan. 29, 2020

(30) Foreign Application Priority Data
Aug. 25, 2017 (EP) 17187982.8

(51) Int. Cl. H01L 31/02; H01L 31/18

(52) U.S. Cl. CPC H01L 31/02013; H01L 31/18; H01L 31/0201

(57) ABSTRACT

The invention relates to a connector for connecting a first solar cell electrode to a further element, wherein the connector has a metallic conductor structure and the conductor structure is coated along the periphery thereof alternately in a circumferential manner with two respective continuous areas of materials A and B, wherein A is a solder material and B is a dielectric material, characterized in that the surface area of each orthogonal projection of the entire connector is at least 10% larger than the surface area of the orthogonal projection of each of the areas of material A. The invention further relates to a method for producing the connector and to a photovoltaic component containing the connector according to the invention.

The present invention relates to a connector for connecting a solar cell electrode with a further element and a method for the manufacture thereof, as well as a photovoltaic component inside which the connector is used.

A solar cell is typically made up of at least one semiconductor layer that is contacted by at least two electrodes of different polarities. In most cases, the semiconductor layer is a doped silicon layer that is present in the form of a monocrystalline or multicrystalline silicon wafer. The differently polarized electrodes are usually arranged on opposite sides of the semiconductor layer. A charge separation occurs in the semiconductor layer when light hits the solar cell, and the charges can be tapped as a current on the electrodes. A plurality of thin electrodes that span the semiconductor layer like a thin mesh are located on the incident light side to efficiently capture charges over the entire surface area of the semiconductor layer. These thin electrodes on the incident light side are also referred to as finger electrodes. The finger electrodes are usually very thin to ensure that they shadow the semiconductor surface area as little as possible. The finger electrodes often have a width in the range of 20 to 150 μm.

To efficiently transport the charge carriers captured by the finger electrodes, said finger electrodes are connected to one or to a plurality of busbars. The busbars have a larger wire cross-section than the finger electrodes and are mechanically more robust than the finger electrodes. Due to their larger surface area and their mechanical robustness, they are used, inter alia, as contact areas for connecting the solar cells. Busbars typically have a width in the range of 0.1 to 2 mm. A solar cell can include one or multiple busbars. To be able to tap higher voltages, a plurality of solar cells is connected in series, thereby combining them into photovoltaic modules. The solar cell electrodes of adjacent solar cells are connected to a connector to thereby connect a plurality of solar cells to obtain photovoltaic modules.

Typically, the connector is a metal strip, particularly a copper strip. In most instances, contacting of the solar cell electrodes, particularly of the busbars, is achieved by means of soldering. To this end, a copper strip is completely coated with a thin layer of a solder alloy, for example, by means of dip coating, and this coated copper strip is subsequently soldered to the electrodes of two solar cells by heating. In the most widely used scenario, the connector connects the front electrode of a first solar cell to the back electrode of a further solar cell, wherein front and back electrodes have different polarities. To guarantee a long operating life of the photovoltaic modules, it is desirable for the contact between the connector and the solar cell electrode to have a high level of mechanical strength and a high level of electrical conductivity. In most cases, a connector contacts a mechanically robust busbar, wherein the busbar in turn contacts a plurality of finger electrodes. The busbar and connector are typically connected to each other by means of soldering.

Development efforts are trending to increasingly more and increasingly thinner busbars to achieve minimal shadowing of the active semiconductor layer of the solar cell, in as much as this is possible. If the connector and busbar are of equal width, in conventional connectors that are completely coated with a solder alloy, it is possible for liquid solder to flow beyond the busbar during the soldering process, thereby also wetting one or several finger electrodes. A finger electrode can suffer chemical and mechanical damage, when it comes into contact with the liquid solder alloy. Corrosion, for example, can reduce the conductivity or even cut off the contact completely. As a result, transporting captured electrical charges away from the area of the interrupted fingers is poorer or not existent at all and, in effect, the efficiency of the solar cell is ultimately reduced. Even if the finger electrode is not directly damaged when it comes into contact with the solder alloy, the probability increases that the soldered finger electrode is disrupted consequent to the alternating thermal stress over the life of the solar cell due to corrosion. It is therefore desirable to avoid soldering the finger electrodes during production.

It was the object of the present invention to provide a connector that overcomes the disadvantages of the prior art and, in particular, to provide a connector that prevents soldering of the finger electrodes when a busbar is used that has the same or a similar width as the connector. This has become increasingly important, particularly in view of the currently observable trend that provides for increasing the number of busbars per cell while simultaneously reducing the width of the busbars.

A further object of the invention consisted in providing a simple method for producing the connector according to the invention.

The invention preferably also provides a solution for saving solder material, in contrast to a connector that is completely coated with solder.

The objects are achieved with a connector for connecting a first solar cell electrode to a further element, wherein the connector has a metallic conductor structure and the conductor structure is coated along the periphery thereof alternately in a circumferential manner with two respective continuous areas of materials A and B, wherein A is a solder material and B is a dielectric material, characterized in that the surface area of each orthogonal projection of the entire connector is at least 10% larger than the surface area of the orthogonal projection of each of the areas of material A. Thus, preferably, the connector according to the invention can be understood as a conductor structure coated with two strips of material A and B that are separate from each other along the main direction.

It has been found in the context of the present invention that the connector according to the invention does a particularly good job of minimizing or avoiding damage to the finger electrodes during the soldering process, which is why it is suited for connecting solar cell electrodes, for example, busbars with a small width.

The conductor structure is preferably symmetrically coated along the periphery thereof, alternately by areas of material A and material B. In this context, symmetrical means that the areas of material A and B are arranged on opposite sides of the conductor structure. Due to a symmetrical coating, the connector has no preferred alignment during the production process in that it can contact a solar cell electrode by both sides thereof, particularly top and bottom. This way, it is possible to simplify the handling of the connector during the production process of a photovoltaic module.

It is a further advantage of the connector according to the invention that the solder material A cannot come into contact with the finger electrodes during the soldering process, whereby soldering the finger electrodes can be prevented.

### Definitions

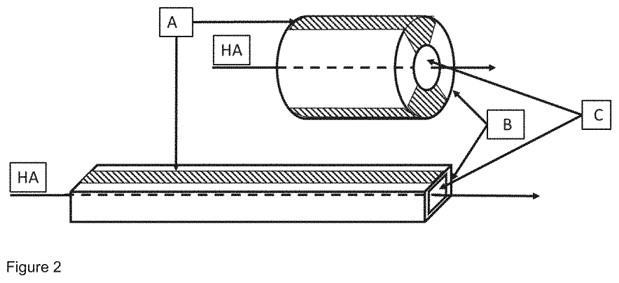

Main axis: In the context of the invention, the main axis refers to the axis along the longest direction of extension of the conductor structure. The main axis is typically identical with the main direction of current flow. Embodiments of a main axis (HA) are depicted in FIG. 2 by way of arrows through the conductor structures (C).

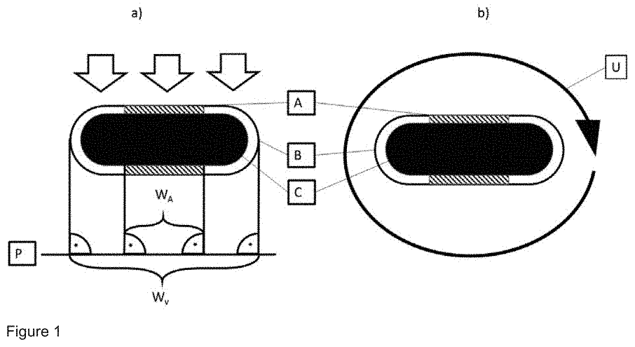

Periphery: The periphery of the conductor structure is understood as an imagined line that extends along the surface of the conductor structure, wherein each point on this line is perpendicular relative to the same point on the main axis. FIG. 1b) depicts the course of the periphery in an exemplary manner by means of the bent arrow (U), wherein a connector according to the invention is depicted by the connector's cross-section.

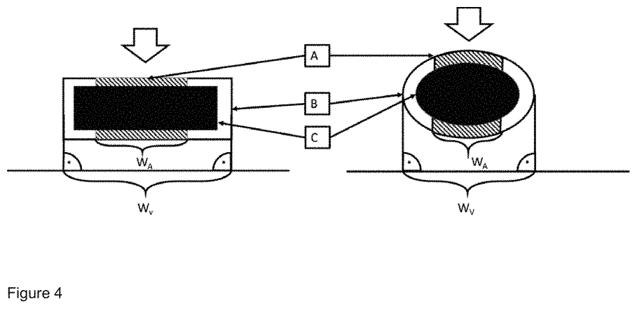

Orthogonal projection: The orthogonal projection is understood to mean a projection of a three-dimensional body on a two-dimensional projection plane that is achieved in that each point of the body is projected perpendicularly on said plane relative to the projection plane. The term orthogonal projection is used as a synonym of “perpendicular parallel projection.” An exemplary orthogonal projection is depicted in FIG. 1a), seen on a cross-section of the connector. The thick arrows in FIG. 1 a) indicate the direction of the projection. In FIGS. 1 a) and b), A is: layer of material A, B: layer of material B, C: conductor structure, W_{V}: orthogonal projection of the connector (in 2D), W_{A}: orthogonal projection of the layer of material A (in 2D) and P: projection area. The designations A, B, C, W_{V}, W_{A} apply throughout for all drawings. It can be seen in FIG. 1 that W_{V} is larger than W_{A}. The above-mentioned condition for the orthogonal projections W_{V} and W_{A} preferably applies independently of the shape of the cross-section of the connector. FIGS. 4 a) and b) show additional exemplary orthogonal projections of connectors having rectangular and elliptical cross-sections.

The present invention relates to a connector for connecting a first solar cell electrode, particularly a busbar, to a further element. The further element is preferably a solar cell electrode of a further solar cell or a connection line for a photovoltaic module. The connector according to the invention is preferably used to connect a plurality of solar cells in series.

A solar cell contains at least the following: one semiconductor layer, one positive solar cell electrode (cathode) and one negative solar cell electrode (anode). For purposes of the invention, a solar cell electrode is always disposed on a solar cell. Positive and negative electrodes are preferably disposed on different sides of the semiconductor layer. Alternatively, the electrodes of different polarities can also be disposed on the same side of the semiconductor layer (so-called back contact cells). The connector preferably connects the positive solar cell electrode of a first solar cell to the negative solar cell electrode of a further solar cell. The connector preferably has a high wire cross-section and a high conductivity for transporting current efficiently away from the solar cell electrodes, particularly the busbars. Moreover, connectors can establish a mechanically and electrically stable connection between the electrodes of the solar cells. This can be achieved by the connector according to the invention in that the connector comprises a solder material.

The connector comprises a metallic conductor structure. The conductor structure preferably contains copper, or it is made of copper. If the conductor structure is made of copper, this means that the conductor structure has at least 99.90% by weight copper. According to a preferred embodiment, the conductor structure can be made of copper that is compliant with the industrial standard Cu-ETP or Cu-OFC.

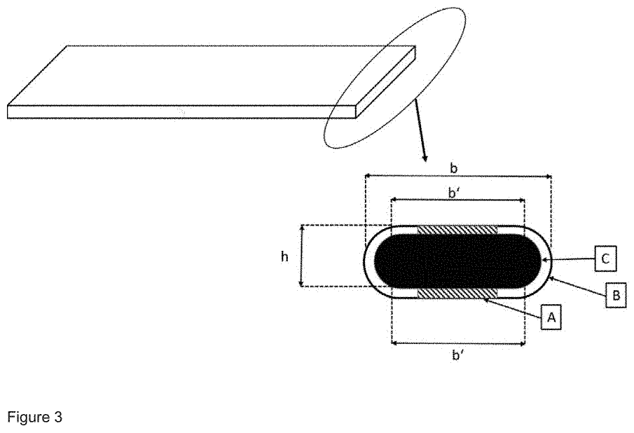

The metallic conductor structure can be a metal strip or a metal wire. A preferred metal conductor structure is a strip, particularly a copper strip. The metal wire preferably has a spherical, elliptical or square cross-section. The aspect ratio of the cross-section of the wire is preferably 0.8 to 1.2. The aspect ratio is the quotient of the length and the width of the cross-section of the conductor structure. The metal strip preferably has a rectangular or almost rectangular cross-section. For an almost rectangular cross-section, the wide side b on the metal strip can have surface areas b′ that are arranged in parallel relative to each other at the top and the bottom of the metal strip, while the short side h can be partially or completely rounded. FIG. 3 shows an example of a rounded side h. A cross-section of the metal strip having parallel wide sides b′ and rounded sides h can be obtained, for example, by flattening a round wire by means of rolling. The width b of the metal strip is preferably at least twice as long as the height h is high. The preferred side length of the shorter side h is in the range of 0.1 mm to 0.4 mm, particularly in the range of 0.16 mm to 0.3 mm. The side length of the long sides b is preferably in the range of 0.6 to 2.0 mm, particularly in the range of 0.9 mm to 1.5 mm. The metallic conductor structure has a main axis (HA) along the longest direction of extension thereof (for example, as indicated by arrows through the conductor structure in FIG. 2). In a preferred embodiment, the main axis extends along the direction of the current.

The length of the conductor structure along the main axis is not limited any further. The conductor structure preferably has a length that is sufficient for connecting two solar cells, which are positioned adjacent to each other, by means of their electrodes, particularly their busbars. To this end, the length of the conductor structure can be twice a long, for example, as the length of a solar cell that is to be connected. Specifically, the length of the conductor structure is in the range of 100 to 600 mm, particularly preferred in the range of 200 to 400 mm.

The metallic conductor structure preferably has at least one of the following mechanical characteristics:
A tensile stress Rm in the range of 100 to 300 MPa, preferably max. 280 MPa.
A yield point Rp0.2 in the range of 40 to 120 MP, preferably max. 80 MPa
An elongation at break A100 in the range of 10 to 40%, preferably min. 25%

Optionally, the conductor structure can have several or all of the mentioned mechanical characteristics.

The conductor structure is coated along the periphery thereof (meaning about the main axis) alternately with two respective continuous areas of materials A and B. The areas alternating along the periphery can preferably also be understood to mean strips along the main axis of the conductor structure. In a preferred embodiment, the strips can extend as straight or spiral-shaped along the surface of the conductor structure. Preferably, the materials A and B coat the conductor structure along the main direction so completely that there are no gaps remaining between the areas that have been coated, respectively, with the material A and material B; i.e., the surface of the conductor structure is completely covered and not directly accessible, at least along the main axis. The ends of the conductor structure, particularly the ends of the metal strip or metal wire, can be coated either with material A or material B, or they can be free of any coating altogether. Due to the coating that extends along the periphery in a circumferential manner, the entire surface of the conductor structure is preferably covered either by material A or material B. In a particularly preferred embodiment, material A can overlap material B partially. Due to the coating that extends along the periphery alternately in a circumferential manner, the conductor structure is preferably especially well protected against environmental influences that can result in corrosion of the conductor structure. The result is an electrical contact between the connector and a solar cell electrode that is particularly resistant to aging.

Material A is a solder material. The terms material A, solder material A and solder material are used synonymously in this application. The solder material preferably contains a solder alloy, or it is made of a solder alloy. A solder alloy is a metallic mixture of elements, and at least one of said elements is a metal. Preferably, all of the elements of the alloy are metals. The solder alloy preferably has a melting point that is at least 100° C., particularly at least 200° C., below the melting temperature of the conductor structure. Preferred solder alloys contain elements selected from the group consisting of Sn, Pb, Ag, Bi, Cu, Zn, Au, Sb, Cd, Co and Al. The solder alloy consists preferably of at least two of these elements. Particularly preferred solder alloys are selected from the group containing SnPb, SnPbAg, SnPbBi, SnAg, SnAgBi, SnAgCu, SnBi and SnCu.

The solder alloy can be selected from lead-containing solder alloys and from lead-free solder alloys. Particularly preferred lead-containing solder alloys are selected from the group consisting of Sn₆₂Pb₃₆Ag₂, Sn₆₃Pb₃₇ and Sn₆₀Pb₄₀. Particularly preferred lead-free solder alloys are selected from the group consisting of Sn_{96.5}Ag_{3.5}, Sn_{96.5}Ag₃Cu_{0.5}, Sn₆₀Bi₄₀, Sn₅₀Bi₄₈Ag₂, Sn₄₂Bi₅₇Ag₁, Sn₄₃Bi₅₇, Sn₅₀Bi₅₀ and Sn_{99.3}Cu_{0.7}. Aside from unavoidable contaminations, the solder material can consist of the solder alloy. The total quantity of components that cannot be considered part of the solder alloy is preferably no more than 0.1% by weight, particularly no more than 0.01% by weight.

Alternatively, the solder material can contain a solder alloy, wherein the solder material contains additionally other components. The solder material can include, for example, fluxes, solvents and other additives. The flux is preferably selected from organic acids, such as, for example, colophony or adipic acid, inorganic salts, such as, for example, ammonium chloride, inorganic acids, such as, for example, phosphoric acid. The fluxes are preferably free of any halides. Preferably, the solvent is an organic or aqueous solvent. The additives are preferably activators. Known activators are compounds that contain halogens, for example. The portion of the mentioned further components of the solder material (for example, fluxes, solvents and activators) is preferably in the range of 1% by weight or less, particularly in the range of 0.1% by weight or less. In a preferred embodiment, the further components of the solder material can be residues of a solder paste, of the kind as described in the context of the method for producing the connector according to the invention.

The layer thickness of the areas of material A alternating along the periphery is preferably in the range of 1 μm to 40 μm and particularly preferred in the range of 10 μm to 20 μm.

Material B is a dielectric material. Preferably, material B comprises a polymer material or a ceramic. Particularly, material B comprises a polymer material or a ceramic. Material B is, particularly, selected in such a manner that it is not wetted by any molten solder alloy, such as the kind that is used as material A. The polymer material can contain a homopolymer or a copolymer. The polymer material can have duroplastic or thermoplastic characteristics. Duroplastic materials are generally understood to be materials that cannot be deformed when they are being heated. It is particularly preferred for the polymer material to be a duroplastic material. Duroplasts are preferably produced by the chemical crosslinking of resins, particularly artificial resins and natural resins. The artificial resins are preferably selected from epoxy resins, polyester resins and acrylate resins. The resin can be a single- or multi-component system. The curing and/or crosslinking of the resin is preferably initiated by means of UV light, by heat or by adding a further component. The further component can be, for example, a crosslinker, a catalyst or an initiator. It is particularly preferred for the polymer material to be a crosslinked lacquer, for example, a solder stop mask. In areas where the solder stop mask has been applied, it can prevent wetting of the surface of the conductor structure with molten solder alloy. The solder stop mask can preferably contain a cured, particularly crosslinked, epoxy resin. The polymer material that is used as material B is particularly preferably UV-cured; i.e., the used resin is crosslinked under the influence of UV light (at a wavelength of about 200 to 400 nm).

According to a preferred embodiment, the material B has a modulus of elasticity of 7 GPa or less, particularly of 5 GPa or less and particularly preferably of 2 GPa or less. The portion of the coating with material B relative to the total surface of the conductor structure is preferably 5 to 95% and preferably 30 to 80% of the total surface area of the connector. According to a preferred embodiment, the polymer material comprises at least one filler. The at least one filler can be an organic or inorganic filler. Particularly, the filler can be present in particle form. The inorganic filler can be a metal oxide, for example, that is selected from the group consisting of TiO₂, ZnO, SiO₂, ZrO₂, SnO₂, CaO and Al₂O₃. Preferably, the filler has light-scattering characteristics. Preferably, the filler is present as particles distributed within the polymer material. Since material B is a dielectric material, it acts as an insulator. Insofar, the insulation effect relates to the layer of material B as a whole. According to the invention, it is not precluded that the material B, when present in form of a polymer material, comprises metallic particles as a filler. The filler content or the metallic particles in the polymer material is preferably held to such a low level that the layer of the polymer material as a whole does not exhibit increased electrical conductivity in comparison to a polymer material without filler. Preferably, the metallic particles scatter the visible light, particularly the incident sunlight on the connector, and they preferably do not melt at the solder temperature of the solder material.

If the material B, particularly the polymer material, contains a light-scattering filler, the incident sunlight on the connector can be scattered in such a way that it does not exit from the solar cell and/or the photovoltaic module manufactured therefrom; instead, due to internal reflection, it reaches the active semiconductor layer and generates additional charge carriers there. This way, the level of efficiency of the solar cell can be improved.

The thickness of the layer of material B is preferably in the range of 1 μm to 40 μm and particularly preferred in the range of 10 μm to 20 μm. It is particularly preferred that the layer thickness of material B corresponds to the layer thickness of material A.

The two areas of material A that extend along the main axis of the conductor structure, respectively, are disposed in such a way that the surface area of each orthogonal projection of the total connector is at least 10% larger than the surface area of the orthogonal projection of each of the areas of material A, independently of the selected projection direction. Particularly preferably, the surface area of each orthogonal projection of the total connector is at least 30% and very particularly preferably at least 50% larger than the surface area of the orthogonal projection of each of the areas of material A.

The projection scenarios that are mentioned in this application particularly refer to projections in which an area of material A has the shortest possible distance relative to the projection surface area. This specific projection corresponds to the use of the connector in the context of a solar cell in which an area of the solder material A is facing the surface of the solar cell to contact the same. According to a preferred embodiment, the connector is designed in such a way that the orthogonal projection of each of the areas of material A is at an equal distance, respectively, relative to the edges of the orthogonal projection of the overall connector. The areas of material A are preferably disposed in such a way that the orthogonal projection of each area of material A is symmetrically oriented relative to the orthogonal projection of the overall connector.

The widths of the two areas of material A that alternate along the periphery can be equal or different. The widths of the two areas of material B that alternate along the periphery can be equal or different.

The portion of the material B as part of the total surface area of the conductor structure covers preferably 5 to 95%, particularly 30 to 80% and particularly preferably 40 to 60% of the total surface area. According to a particularly preferred embodiment, in areas where the connector is not in contact with the solar cell electrodes that are to be connected, which is between two solar cells within a photovoltaic module, the conductor structure is completely surrounded by a layer of material B. This way, it is possible to save solder material.

The connector comprises two areas of material A alternating along the periphery and separated from each other by areas of material B. It is advantageous therein when the areas of material A alternating along the periphery are disposed in such a way that the two areas of material A are symmetrically located on opposite sides of the conductor structure. Accordingly, it is possible to connect front electrodes to back electrodes.

The invention moreover relates to a method for producing the connector that is suitable for connecting a first solar cell electrode to a further element, comprising the steps of:
a) providing a metallic conductor structure,
b) partially coating a metallic conductor structure along the main axis of two areas that are separate from each other with a dielectric material B, and
c) partially coating the metallic conductor structure along the main axis of two areas that are separate from each other along the periphery with a solder material A,
wherein the partial coating with the materials A and B is achieved in such a way that the conductor structure is alternately coated along the periphery with these materials.

According to the method according to the invention, step a) necessarily precedes steps b) and c). The order of the steps b) and c) is not specified any further, which is also reflected in the use of the term “comprising”. According to a preferred embodiment, step b) precedes step c).

The method according to the invention does not preclude performing further steps in between or following the steps a) to c).

According to a preferred embodiment, the provided conductor structure is cleaned in step a) and thereby freed of any residues, such as, for example, greases and oxides.

Step a) provides a metallic conductor structure as described in this application. The conductor structure is preferably provided as a continuous strip or as a continuous wire on a roll. The wound-up conductor structure can preferably measure a length of several hundred to several thousand meters. If the conductor structure is provided in the form of a roll, in step a), the conductor structure is preferably unwound from the roll. According to a particularly referred embodiment, step a) also includes, in addition, a pretreatment. The pretreatment can be selected, for example, from soft annealing and plasma etching in an inert atmosphere. The inert atmosphere can be, for example, a nitrogen or argon atmosphere. If the conductor structure is treated with soft annealing and plasma etching, the entire production process of the connector is carried out in an inert gas atmosphere.

In step b), the metallic conductor structure is coated along the main axis with two surface areas that are separate from each other by a dielectric material B.

Preferably, the coating process in step b) consists of two subordinated steps. In the first subordinated step, material B or a precursor of material B is applied to the conductor structure, and, in a second subordinate step, material B or a precursor of material B is fixed on the conductor structure. If the material B is a ceramic, preferably, a precursor of material B is applied in form of a ceramic-containing paste, which contains ceramics particles. If material B is a polymer material, preferably, a cross-linkable resin (particularly, an artificial resin) or a lacquer is applied to the conductor structure. A cross-linkable resin and a lacquer can be precursors of material B that can be fixed in a further subordinated step. The lacquer can be a solder stop mask that prevents liquid solder alloy in the applied areas from wetting the surface of the conductor structure.

Preferably, the dielectric material B is applied by means of printing or common extrusion processes. The printing process can be a contact printing process or a contactless printing process. The contact printing process can be selected from the group consisting of high-pressure printing, planographic printing (for example, offset printing) and intaglio printing. According to one embodiment, each of the aforementioned printing processes can be executed as a rotary printing process. Preferably, the material B is continuously applied to the conductor structure, for example, by a roller-to-roller process. To this end, it is advantageous for the conductor structure (for example, a metal strip) to be advanced continuously to a printer head. The printer head has corresponding cutouts where the coating of the conductor structure with material B can be effected. The areas of the conductor structure that are outside of the cutouts are kept free from being coated with material B by means of shutters or by introducing gas or solvent flows.

According to another preferred embodiment, material B or the precursor for material B can be applied to the conductor structure by a contactless printing process. The contactless printing process can be selected, for example, from spraying, inkjet printing or dispensing.

According to a preferred embodiment, while being coated with material B, the conductor structure has a temperature in the range of 40 to 70° C., preferably about 60±5° C. The printing process onto the conductor structure is preferably carried out at an application speed of at least 100 m/min or preferably up to 300 m/min, wherein the distance information in meters refers to the length of the printed conductor structure.

According to a further preferred embodiment, material B can be applied to the conductor structure as a film, which is laminated onto the conductor structure. The film can be, for example, a polymer film.

In a second subordinated step, the layer of material B and/or of the precursor of material B is optionally fixed. By said fixing, it is possible to chemically alter the material B that was applied in the first subordinated step, such as, for example, by means of the crosslinking reaction of a polymer mesh. If a ceramic paste was applied to the conductor structure, the fixing is preferably carried out by means of baking. Fixing a ceramic paste preferably does not alter the composition of the ceramic.

The fixing of the polymer material that was applied in the form of a resin or lacquer in the first subordinated step is preferably carried by using UV radiation (for example, a broadband UV radiator) or heat supply. Preferably, a crosslinking reaction occurs during the fixing of the resin or lacquer.

If a film is applied to the conductor structure, the same is preferably fixed. In particular, the film is heated at least in part to the melting temperature. Heating will preferably improve the adhesion of the film relative to the conductor structure. According to an alternative preferred embodiment, the film is not treated in a further subordinated step.

By said fixing the coating of material B or of a precursor of material B, which was applied to the conductor structure in the first subordinated step, in this second subordinated step, it is possible to increase, inter alia, the adhesion of the layer relative to the conductor structure and the layer of material B itself can be rendered more resilient against mechanical and chemical influences.

According to a further preferred embodiment of step b), the conductor structure is first completely coated with material B. Subsequently, the coating of material B is partially removed again resulting in two areas of material B along the main axis of the conductor structure that are separate of each other. Said partial removal can be achieved, for example, by means of laser ablation. According to a particularly preferred embodiment, the conductor structure is first completely coated with a precursor of material B, particularly a solder stop mask, which is then fixed, particularly crosslinked, and subsequently the fixed material B is partially removed with laser ablation. This laser ablation once again exposes partial areas of the surface of the laser structure.

According to a preferred embodiment, after said fixing, the material B has a modulus of elasticity of 7 GPa or less, particularly of 5 GPa or less and particularly preferred of 2 GPa or less. The portion of the coating with material B on the total surface of the conductor structure is 5 to 95%, preferably 30 to 80%.

According to a particularly preferred embodiment, a pretreatment is carried out prior to step c). For example, the pretreatment can include the application of a flux on the areas of the conductor structure that are not coated with material B. Said application can be necessary, particularly, if the production process of the connector is not performed entirely in an inert gas atmosphere. Preferably, an inert gas atmosphere does not contain more than 1% by volume oxygen.

Step c) includes a partial coating of the metallic conductor structure along the main axis with two areas that are separate from each other using a solder material A. Preferably, the coating of the conductor structure with solder material A is carried out in the areas that are not coated with material B. When working with a copper strip, only the free copper surface is covered with solder material, for example. The liquid, molten solder alloy preferably does not wet the coating of material B, which is preferably a polymer material and particularly a cured solder stop mask.

The conductor structure can be coated with solder material A in different ways. According to a preferred embodiment, the conductor structure, which was coated previously with material B, can be coated with material A by dip coating. In dip coating, the conductor structure, which was coated previously with material B, can be immersed in a molten bath of a liquid solder alloy or a bath of a solder paste. A dip coating has the advantage that it particularly easily allows for producing alternately circumferential areas of material A along the periphery of the conductor structure that has been pre-coated with material B. Employing dip coating, it is possible to coat the areas of the conductor structure along the main direction thereof that are not coated with material B with material A. Preferably, the conductor structure is immersed in a bath of a liquid solder alloy. The conductor structure, particularly a copper strip, is preferably continuously advanced through a molten bath of a solder alloy. The solder alloy of the molten bath preferably has a melting point that is at least 100° C., particularly at least 200° C., below the melting temperature of the conductor structure. The solder alloy can be selected from solder alloys that have been described herein.

Any excess liquid solder alloy can subsequently be removed, for example, by means of compressed air or by wiping. The layer of liquid solder alloy on the conductor structure preferably has the same layer thickness as the layer of material B. According to an alternative embodiment, the layer of material A is thicker than the layer of material B. The layer thickness of the layer of material B can be uniform or varied.

After passing through the molten bath, the liquid solder alloy can cool down and harden, thus forming along the periphery thereof alternating areas of the solder material A and the dielectric material B on the conductor structure.

According to an alternative embodiment of the invention, the conductor structure, which has been coated previously with material B, can be coated with a solder paste by means of printing. The solder paste preferably contains at least particles of a solder alloy and a flux. The solder paste can also comprise solvents and additives. The solvents can be organic or aqueous solvents. The additives can be, preferably, rheology modifiers, such as, for example, thixotropic agents, thickeners or resins. The solvent can be an organic solvent or an aqueous solvent.

In a first step, the solder paste is printed onto the areas of the conductor structure that are not coated with material B. In a further step after said coating, the solder paste can be fixed on the conductor structure. Said fixing of the solder paste is preferably carried out by means of warming or heating. Warming means, in this context, that the solder paste is warmed to a temperature that is below the melting point or the contained solder alloy, whereby the layer of the paste dries and volatile components escape. Heating means, in this context, that the layer of the solder paste is heated to a temperature that is above the melting point of the contained solder alloy. When heating, a continuous layer of a solder alloy is preferably formed while the volatile components of the paste are for the most part removed such as, for example, by evaporating or incinerating. This way, it is possible to produce a connector according to the invention.

As outlined above, the order of the steps b) and c) is not further specified. According to an advantageous embodiment of the invention, the connector can be produced by first applying a layer of the solder material A along the main axis of the conductor structure, followed by a layer of the dielectric material B. This process order can be implemented, for example, by first applying a solder material A in the form of a solder paste to areas that are separate from each other along the main axis of the conductor structure, followed by applying two separate areas of a layer of material B to the surface areas that are not coated by material A. In this embodiment, wherein step b) follows after step c), material A and material B are both preferably applied by a printing process, respectively.

On the connector that was produced according to the invention, areas coated with material B and areas coated with material A alternate along the periphery of the connector. The two areas of the conductor structure that are coated with material A and material B and that are separate from each other continuously coat the conductor structure along the main axis thereof.

If the conductor structure is provided as a continuous strip or wire in step a), after completing steps b) and c), the conductor structure is preferably cut into single pieces, whereby the finished connector is obtained. The length of the cut-up conductor structure is preferably in the range of 100 to 600 mm, particularly preferred in the range of 200 to 400 m.

The conductor structure that was coated in steps b) and c) can optionally, following the completed coating process, be rewound onto a roll (also referred to as a coil). Particularly preferably, the conductor structure is rewound after steps b) and c) and not unwound again until needed for the process of producing a photovoltaic component, when it is cut to the respectively necessary length for the application.

According to an embodiment, the invention relates to a photovoltaic component, comprising a first solar cell electrode and a further element, wherein the solar cell electrode and the further element are connected to each other by means of a connector according to the invention. The first solar cell electrode of the photovoltaic component is preferably a front or back electrode. A solar cell preferably contains at least one semiconductor layer that is contacted by at least two solar cell electrodes of different polarities. The semiconductor layer is preferably a doped silicon wafer. The semiconductor layer is preferably a monocrystalline or multicrystalline silicon wafer. The at least two solar cell electrodes of a solar cell are typically at least one back electrode and at least one front electrode, which means the electrodes are disposed on opposite sides of the semiconductor layer. The front electrode is located on the side with incident light, while the back electrode is on the side facing away from the light. According to another embodiment, it is possible to dispose said at least two electrodes on the same side of the semiconductor substrate (also referred to as back contact solar cell).

The back electrode can be, for example, a two-dimensionally applied metal layer. The metal layer preferably contains aluminum with silver-containing contact sites.

The front electrode of the photovoltaic component is preferably a busbar. The busbar can connect a plurality or all finger electrodes to each other and is used to efficiently transport the current captured by the finger electrodes. Simultaneously, the busbar can be used to provide mechanically robust contact surfaces, for example, for soldering. Preferably, the bus bar has a larger wire cross-section than a finger electrode. Preferably, the diameter of a busbar can be in the range of 100 μm to 2 mm, the height is preferably 1 to 20 μm. A person skilled in the art is familiar with different busbar designs. A busbar can be designed as a continuous, uniform conductor path, a constricted conductor path (for example, in form of a string of pearls) and with interruptions. According to a preferred embodiment, a busbar contacts a plurality of, particularly all, present finger electrodes. Preferably, the connector is wider than the busbar to facilitate a correct alignment of the connector relative to the busbar. To achieve minimal shadowing of the semiconductor layer, in as much as possible, the widths of the connector and the busbar preferably differ by 50% or less, particularly 20% or less and particularly preferred by 10% or less.

Preferably, the back and the front electrodes are produced by applying a conductor paste onto the semiconductor layer and subsequently baking the applied conductor paste. The conductor paste can be applied to the semiconductor layer by means of printing, such as, for example, screen or stencil printing. A conductor paste typically comprises electrically conducting metal particles, glass frit or an organic medium. If the conductor paste is used in the production of a back electrode, the electrically conductive metal particles preferably contain silver and/or aluminum. If the conductor paste is used in the production of a front electrode, the electrically conductive metal particles are preferably made of or contain silver. After the application thereof, the semiconductor substrate can be baked together with the, for example, applied conductor paste(s), which results in a solar cell electrode. The organic medium can be removed by said baking, and a mechanically solid and electrically conductive electrode is thereby obtained. Thus, the obtained solar cell electrodes preferably comprise a mixture of glass and metal.

In a photovoltaic component according to the invention, a first solar cell electrode is connected by means of the connector according to the invention to a further element. Preferably, the further element is a further solar cell electrode of a solar cell. It is particularly preferred for the further element to be a further solar cell electrode having a polarity that is the opposite polarity of the polarity of the first solar cell electrode. The first solar cell and the further solar cell can be identical, for example. The connector preferably connects the front electrode of the first solar cell to the back electrode of the further solar cell. Alternatively, the connector can also connect the back electrode of a first solar cell to the front electrode of a further solar cell. The photovoltaic component according to the invention can also be part of a chain of solar cells that are connected by the connector; i.e., aside from a first and the further solar cell electrodes, still further solar cell electrodes can be connected to further connectors, respectively.

According to a preferred embodiment, the contact between the first solar cell electrode and the connector is established by a solder connection. Preferably, the solder connection is established by melting at least one area of material A onto the connector. An alternating area on the connector along the periphery thereof, which is coated with a solder material A, contributes to the mechanical and electrical contacts relative to the first solar cell electrode. Particularly advantageously, the electrical contact between the connector and the solar cell electrode is established by means of a first area of material A, and the electrical contact between the connector and the further element is established by means of a second area of material A, wherein the areas of material A are separated from each other by a layer of material B arranged there between, respectively. Alternatively, the contact between the connector and first solar cell electrode and between the connector and the further element can be provided by means of the same area of solder material A.

Since the connector according to the invention is coated in part with material B in the contact area with the first solar cell electrode and in the contact area with the further element, it is possible to prevent the finger electrodes from coming into contact with material A, when the solar cell electrode is soldered to the connector. In particular, the solder area formed by the molten solder material is delimited by the areas of material B, whereby liquid solder material preferably cannot come into contact with the finger electrodes.

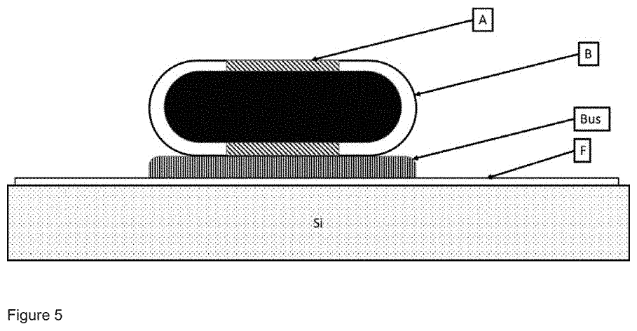

FIG. 5 shows a cross-section of the connector according to the invention that is in contact with a busbar (bus) via the solder material A. Here, the connector only contacts the busbar (bus), and it does not contact the finger electrode (F), because the material A is delimited by the material B. In FIG. 5, Si designates a silicon wafer. The surface area where the connector and the busbar are in contact with each other is designated the contact area.

The alternating areas of material B that extend along the periphery of the photovoltaic component according to the invention have dielectric characteristics and preferably do not contribute to the electrical contact between the solar cell electrode and the connector. According to a preferred embodiment, the alternating areas of material B that extend along the periphery contribute to establishing the mechanical contact, for example, by means of adhesion, in that material B acts as a glue.

The photovoltaic component according to the invention is preferably produced by a process that comprises the following steps:
providing a solar cell having at least one solar cell electrode, particularly a busbar, and providing a further element,
providing a connector according to the invention,
positioning the connector relative to the at least one solar cell electrode and the further element,
connecting the at least one solar cell electrode and the further element by means of the connector.

The section below describes the production of a photovoltaic component, wherein a connector connects a solar cell electrode to a further element. However, the invention also comprises embodiments where a solar cell includes a plurality of solar cell electrodes, particularly busbars, that are connected via a connector to the further element(s).

A solar cell that includes at least one solar cell electrode is provided for the production of a photovoltaic component. The solar cell preferably comprises at least one front electrode, for example, in the form of a busbar and one back electrode. Preferably, the further element is a further solar cell electrode of a solar cell. Particularly, the further solar cell is identical with the first provided solar cell. Alternatively, the further element of the photovoltaic module can also be a connection line for a photovoltaic module. To this end, the connection line can serve for transporting the current away from a plurality of solar cells that are connected in series.

In addition, at least one connector according to the invention is provided. The connector is preferably provided by unwinding the same from a roll. Preferably, the unwound and already coated conductor structure is cut to the required size, whereby a suitable connector is obtained for the respective application. Specifically, the connector is provided in such a manner that the length thereof is sufficient for connecting the busbar of a solar cell to the solar cell electrode of a further solar cell, particularly a back electrode. This means, in this embodiment, the connector is about twice as long as the length of a solar cell. According to a preferred embodiment, the number of the provided connectors corresponds to the number of the busbars that are present on the solar cell. Specifically, one roll of coated conductor structure, which can be cut to size for the connector according to the invention, is provided per busbar.

To achieve minimal shading of the semiconductor layer, in as much as possible, the widths of the provided connector and the first solar cell electrode, for example, a busbar, preferably differ by 50% or less, particularly 20% or less and particularly preferred by 10% or less. The connector can be wider or smaller than the first solar cell electrode. Preferably, the connector according to the invention is wider than the busbar.

In addition, the provided connector is positioned relative to the solar cell electrode and the further element. To this end, preferably, the provided connector is aligned with the first solar cell electrode, particularly the busbar and, for example, centered over the busbar. Since the connector is preferably longer than the busbar, a portion, such as, for example, half the length of the connector protrudes from the first solar cell.

Subsequently, the further element can be positioned in such a manner that a contact can be created between it and and the connector. If a front electrode of a first solar cell is to be connected to the back electrode of a further solar cell, the connector can first be positioned correspondingly on the front side, and subsequently the further solar cell is positioned by the back side thereof on the protruding portion of the connector.

The connector that is positioned on the solar cell electrode and the further element is subsequently connected to the same. Said connecting preferably occurs by pressing and soldering the positioned connector in place. For said soldering, preferably, the arrangement of solar cell electrode, connector and further element is heated in such a matter that the areas of the solder material A that extend along the periphery of the connector melt, and a solder connection with the solar cell electrode is established. The heating of the solder material preferably occurs by means of infrared radiation.

Since the surface area of each orthogonal projection of the total connector is at least 10% larger than the surface area of the orthogonal projection of each of the areas of material A, and due to the presence of areas of material B, the melted solder material cannot easily wet the overall contact area, which is why the risk of damage to the finger electrodes can be avoided.

Preferably, it can be envisioned that the solar cell electrode and the further element be preheated prior to the actual soldering to minimize mechanical stresses. In addition, the cell connector and the solar cell electrode are preferably pressed together during the solder process. After soldering, in the areas of the connector that are coated alternately along the periphery thereof with solder material A, there is obtained a mechanically solid and electrically conductive connection. A photovoltaic component which provides that the first solar cell electrode is connected to a further solar cell electrode by means of a connector is also designated a photovoltaic module. The connector according to the invention can preferably also be used for connecting more than two solar cells to photovoltaic modules.

The connector according to the invention can be processed in a commonly used industrial process, analogously to copper strips that are completely coated with solder, thereby allowing for the electrical series connection and mechanical connection of solar cells needed for manufacturing solar modules.

Below, the general teaching of the invention will be explained based on concrete embodiments.

### EXAMPLES

1) Producing the Coated Connector:

First, a metallic conductor structure was provided in the form of a copper strip wound up on a coil (copper: ETP standard, Rp0.2=80 MPa, dimensions: 1.5 mm wide, 200 μm thick). The copper strip was unwound from the coil, underwent a thermal treatment (annealing, soft annealing) and surface reduction by means of a plasma treatment. The further steps before the solder bath were carried out in an inert atmosphere (oxygen percentage <50 ppm).

Then, the UV-curing solder stop mask (ELPEPCB® SD 2460/201 UV-FLEX) was applied to the copper strip, in the lateral areas and the partial area for the later contact areas, using an extrusion process. During this step, the strip was pulled through a chamber.

Inside the chamber, the lacquer was under a pressure. Entry and exit were sealed by a narrow gap in such a manner that no lacquer could escape from the chamber. The coating of the edges was continuous via adhering lacquer while being transported through the lacquer inside the chamber. Wetting of the center areas with lacquer was prevented by means of shutters.

The thickness of the lacquer coating was 15 μm. The solder stop mask coated the front and back sides of the copper strip, specifically in such a manner that 1 mm wide areas were created in the contact areas on the front and the back sides that were free of solder stop mask. The applied solder stop mask was subsequently cured with the UV light of a high-pressure mercury vapor lamp and at a substrate surface temperature of about 60° C. After curing, the layer thickness of the lacquer layer was also about 15 μm. In the next step, the copper strip that was partially coated with solder stop mask was immersed in a solder bath that contained molten solder alloy (Sn60Pb40). The layer thickness of the solder was determined therein based on the temperature of the solder bath, the advancing speed of the copper strip and “wiping” with air knives immediately after the exit from the solder bath. After the copper band was removed, areas thereon that were not wetted by solder stop mask, were wetted by solder alloy. The areas of the solder stop mask were not wetted by the solder alloy. After hardening, the layer of the solder alloy had a layer thickness of about 15 μm. After hardening, the coated copper strip was rewound onto a coil.

2) Providing Solar Cells

A p-type cell with n-emitter manufactured by the company Q-Cells was used as a solar cell (resistance: 90 Ohm/square). The surface had a Si3Nx antireflektive coating on the front side. Using the commercially available paste Heraeus SOL 9631C (Heraeus Deutschland GmbH), fingers and three busbars were applied therewith on the front side, using screen printing. The line width of the fingers was 40 μm, and the width of the busbars was 1.5 mm. Screen-printed silver solder pads were applied, with the commercial paste Heraeus SOL205B (Heraeus Deutschland GmbH) on the backs thereof. Aluminum-BSF on the back side was printed on using screen-printed commercial aluminum paste ((RUX28K30, Guangzhou Ruxing Technology Development Co., Ltd. of Guangdong, China). The pastes were dried and baked at a maximum temperature of 900° C. in a furnace.

3) Producing Photovoltaic Modules:

Photovoltaic modules were produced from two solar cells using a connector and the process described below.

A first solar cell was positioned on the mounting surface in such a way that the front electrodes with the busbars were located on top, respectively.

A coated copper strip, as produced in Example 1, was provided wound up on coils. A separate coil with coated copper strip was provided for each or the three busbars per solar cell.

The metal strips, which were alternately coated along the periphery with solder and solder stop mask, were unwound, elongated, and advanced to the busbars using guide means. The coated copper strips were each positioned and aligned above the three busbars in such a manner that a minimum surface area of the front of the solar cells was shaded.

After the unwinding and positioning the connector over the first solar cells, the connectors were cut up in such a manner that the length of the connectors was sufficient for connecting two adjacent solar cells. This means that the length of a cut-to-size connector was twice as long as the length of the first solar cell. One half of each unwound copper strip, respectively, contacted a busbar on the front of the first solar cell, while the other half of the connectors protruded from the solar cell. The second solar cell was placed over the portions of the three connectors that protruded from the first solar cell. The second solar cell was positioned in such a way that the connectors contacted the back of the second solar cell.

After positioning the second solar cell, the solar cell and the three connectors were pressed together. The apparatus of the two solar cells and the connector was heated with IR radiation in such a manner that the solder material on the connector reached a temperature of about 200° C. After said heating, the arrangement was cooled down, whereby the molten solder alloy hardened. Two connected solar cells were obtained in this manner.

4) Measuring and Comparing Different Photovoltaic Modules

For comparison, a further photovoltaic module was produced from two solar cells, wherein the connection of the two solar cell electrodes was achieved with a conventional copper strip that was completely coated with solder alloy (Sn60Pb40).

Two sets of two soldered solar cells were soldered together in series. By then laminating the same, so-called mini-modules of four cells each were produced. These mini-modules were used to measure the serial resistance (Rser), the filling factor (FF) and the electron luminescence (EL), directly after the manufacture as well as after accelerated aging at elevated temperature.

For said accelerated aging, the two produced photovoltaic modules were exposed to cyclical temperature changes between −40 to +55° C. The module output of the photovoltaic modules was tested after 100 and 500 temperature cycles in compliance with the parameters of the standard (IEC 61215). The output STC of the modules was detected at 1000 W/m² and a cell temperature of 25° C. according to IEC 60904.

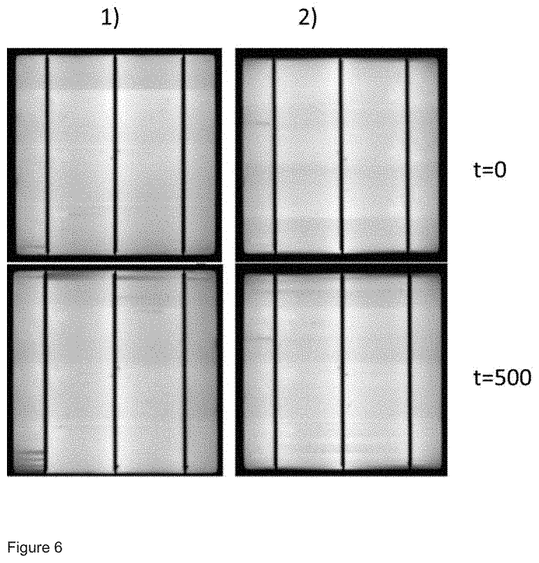

Table 1 compiles the measured results. As seen in Table 1, the filling factor for the comparison module with standard connectors is lower, and/or it continued to decrease after aging. In addition, in the example according to the invention, the drop of the series resistance (Rser) and/or the filling factor (FF) is lower. FIG. 6 shows a measurement of the electroluminescence. Dark stripes on the solar cell indicate the fingers have failed. The number of failures of fingers (dark gray) is lower in the example according to the invention, both before and after accelerated aging.

TABLE 1

| | | | | Rser | FF | EL |
|---|---|---|---|---|---|---|
| | | | | after | after | after |
| Sample cell | Rser | FF | EL | aging | aging | aging |
| connector | t = 0 | | | t = 500 | | |
| 1) Comparison | − | − | − (Failure of | −− | −−− | − (Failure of |
| | | | individual | | | further finger |
| | | | fingers on | | | lines on |
| | | | the busbar) | | | the busbar) |
| 2) Invention | + | + | + (no failure | + | + | + (virtually |
| | | | of the | | | no change in |
| | | | fingers) | | | relation to |
| | | | | | | baseline |
| | | | | | | measurement) |

1. A connector for connecting a first solar cell electrode to a further element, wherein the connector has a metallic conductor structure and the conductor structure is coated along the periphery thereof alternately in a circumferential manner with two respective continuous areas of materials A and B, wherein A is a solder material and B is a dielectric material, characterized in that the surface area of each orthogonal projection of the entire connector is at least 10% larger than the surface area of the orthogonal projection of each of the areas of material A.

2. The connector of claim 1, wherein the surface area of the orthogonal projection of the connector is at least 25% and at most 80% larger than the surface area of the orthogonal projection of each of the areas of material A.

3. The connector of claim 1, wherein the orthogonal projection of each of the areas of material A is at an equal distance, respectively, relative to the edges of the orthogonal projection of the overall connector.

4. The connector of claim 1, wherein the conductor structure is a strip or a wire.

5. The connector of claim 1, wherein the conductor structure contains copper or is made of copper.

6. The connector of claim 1, wherein the dielectric material B includes a filler that is selected from the group of dielectric materials and metallic materials.

7. The connector according to claim 6, wherein the filler is a metal oxide powder.

8. The connector of claim 1, wherein the material B includes a polymer material.

9. The connector of claim 1, wherein the material B has a modulus of elasticity of 7 GPa or less.

10. A method for producing a connector according to claim 1, suitable for connecting a first solar cell electrode to a further element, comprising the steps:
a) providing a metallic conductor structure,
b) partially coating a metallic conductor structure along the main axis of two areas that are separate from each other with a dielectric material B, and
c) partially coating the metallic conductor structure along the main axis with two areas that are separate from each other along the periphery with a solder material A,
wherein the partial coating with the materials A and B is achieved in such a way that the metallic conductor structure is coated along the periphery alternately with these materials.

11. The method of claim 10, wherein the conductor structure is first coated with material B.

12. The method of claim 10, wherein the partial coating with material B is carried out by printing.

13. The method of claim 10, wherein step c) is carried out by immersing the conductor structure in a liquid solder alloy.

14. A photovoltaic component, comprising a first solar cell electrode and a further element, wherein the solar cell electrode and the further element are connected to each other by means of a connector according to claim 1.

15. The photovoltaic component of claim 14, wherein the further element is a further solar cell electrode.

16. The photovoltaic component of claim 14, wherein the first solar cell electrode is a front electrode and the further element is a back electrode
